(19) United States
(12) Patent Application Publication
(10) Pub. No.: US 2014/0354320 A1
(43) Pub. Date: Dec. 4, 2014

(54) APPARATUS AND METHOD FOR TESTING THE INTERCONNECTION OF PHOTOVOLTAIC CELLS

(71) Applicant: Gerardus Johannes Nicolaas Doodeman, Delft (NL)

(72) Inventor: Gerardus Johannes Nicolaas Doodeman, Delft (NL)

(73) Assignee: Nederlandse Organisatie voor Toegepast- natuurwetenschappelijk onderzoek TNO, Delft (NL)

(21) Appl. No.: 14/342,015

(22) PCT Filed: Sep. 3, 2012
(86) PCT No.: PCT/NL2012/050608

§ 371 Date: Jun. 10, 2014

(30) Foreign Application Priority Data
Sep. 1, 2011 (EP) 11179749.4

(51) Int. Cl. G01R 15/18

(52) U.S. Cl. CPC G01R 15/18
USPC 324/754.29

(57) ABSTRACT

Apparatus and method for contactless testing a closed loop electrical connection in particular suited for testing the interconnection of photovoltaic cells in a solar pane. The apparatus comprises two coils. The first coil is a driving coil (11) comprising at least one first winding (15) for generating a varying magnetic field in the area (14) enclosed by the closed loop electrical connection. The second coil is a detection coil (12) comprising at least one second winding (16) for generating a voltage when being subjected to the magnetic field generated by the current in the closed loop electrical connection. The apparatus further comprises a compensation loop (13) for intrinsically compensating the direct mutual induction of the first coil and the second coil. The compensation loop allows the use of uncomplicated electronics for testing the interconnection, which electronics can easily be implemented in a hand held device.

### FIELD OF THE INVENTION

The invention relates to an apparatus and method for testing a closed loop electrical connection. In a particular embodiment it relates to an apparatus for testing the electrical interconnection of photovoltaic cells in a solar module comprising a multiple of photovoltaic cells.

### BACKGROUND

Individual photovoltaic cells, typically having the size of a silicon wafer, have to be combined for making solar panels or solar modules. More in particular the electrodes of different photovoltaic cells have to be connected with each other electrically. This interconnection of individual photovoltaic cells is fragile, in particular during the production process of combining the different cells in a solid solar panel. Furthermore the interconnection might be poor due to failure of materials or processing. Poor interconnections will result in a lower performance of the solar panel, possibly only after a certain laps of time during use. Such a lower performance might be a reduced efficiency resulting in a lower energy output or a reduced lifetime of the panel. For this reason it is desired to have an apparatus for testing the electrical connection both during the production process of the solar panel as well as afterwards. In particular it is desired to have a testing apparatus that allows testing without making mechanical contact with the photovoltaic cells or the solar panel.

A common type of photovoltaic cell comprises a metallized back electrode and a patterned front electrode. However, it is acknowledged that there are also other electrode configurations. A number of photovoltaic cells might be arranged in series by connecting the back electrode of a first photovoltaic cell with the front electrode of a second cell. Poor contact of the wiring between the photovoltaic cells will result in a high electrical resistance. Therefore, by measuring the resistance by well known resistance meters one can test the quality of the electrical contact. Making a mechanical contact during such a test, however, might damage the photovoltaic cell or making mechanical contact with the photovoltaic cells or solar panel might be difficult or even impossible after the solar panel has been produced.

From the German patent publication DE 4440167 an apparatus and method are known for measuring the current distribution in photovoltaic cells and other semiconductor elements. The local heating resulting from spots with a high electrical resistance is, according to this publication, detected by infrared measurement. This method is suited for detecting defects in homogeneous conductors but using this method for detecting defects in patterned structures is cumbersome.

From international patent publication WO 2008/017305 an apparatus and method are known for investigating defects in photovoltaic cells and solar modules. According to this known apparatus, the magnetic fields that are generated during use of the solar module are measured with special magnetic field detectors. According to this known method the investigation is performed when a current flows through the tracks and interconnections as a result of the light falling on the module. Therefore, this test can only be performed when the module under test is subjected to a sufficient intensity of light and the output of the module is connected to a load resistance to allow the flow of a current. Further, the interpretation of the test results is not easy whereas the measured magnetic fields have to be correlated with the resistance of the tracks and interconnections.

From Japanese patent publication JP2003-110122 a method is known for detecting faults of photovoltaic devices, which method is based on the detection of magnetic fields. The method comprises generating an eddy current in the back electrode film by a driving coil and detecting the induced magnetic field by a detecting coil. This publication also discloses an apparatus comprising two coils that are situated in parallel next to each other. A disadvantage of this known apparatus and method is that the driving coil induces directly a current or voltage in the detecting coil due to the direct mutual induction of the two coils, which current or voltage depends on the geometry of the measurement set-up, in particular the distance to the solar panel and the conductivity of the solar panel.

Also known are magnetometers comprising a driving coil, a detection coil, and a compensating coil for compensating the earth magnetic field and other disturbing magnetic fields. Such a magnetometer is disclosed in for example European patent application EP 0 604 810. An alternating current is provided to the driving coil to saturate a ferromagnetic core. The compensation coil is connected to a different voltage source for providing a DC current in the compensation coil to generate a compensating magnetic field. The magnetometers are in particular suited for measuring small magnetic fields accurately.

### SUMMARY

In one aspect, it is an object to provide an apparatus for testing a closed loop electrical connection, more in particular an apparatus that is suitable for detecting defects in the electrical interconnection of photovoltaic cells in a solar module, which apparatus allows accurate contactless testing, is not complex and is easy to use.

In another aspect, it is an object to overcome problems and disadvantages of the above mentioned state of the art. In particular it is an objective to overcome the problem of the direct mutual induction of the driving coil and the detection coil which may result in a voltage in the second coil, even if no closed loop electrical connection is present.

An apparatus for testing a closed loop electrical connection, the apparatus is provided comprising
a first coil comprising at least one first winding enclosing a first coil area for generating a varying magnetic field in the area enclosed by the closed loop electrical connection, and
a second coil comprising at least one second winding enclosing a second coil area for generating a voltage when being subjected to the magnetic field generated by the current in the closed loop electrical connection,
   characterised in that the apparatus further comprises a compensation loop for compensating direct mutual induction of the first coil and the second coil, which compensation loop at least partially covers one of the first and second coil areas or both the first and second coil areas.

An advantage of a compensation loop is that such a loop eliminates or at least significantly reduces the direct mutual induction of the first coil which is the driving coil for generating an alternating magnetic field and the second coil which is the detection coil for detecting a magnetic field. Preferably a compensation loop is used that provides for intrinsic compensation, that is, a compensation loop that operates by means of or in response to the current that flows through the driving coil and/or the magnetic field induced by that current. A further advantage of a compensation loop that provides for intrinsic compensation is that no additional current source and electronics are required. In an embodiment, the intrinsic compensation may operate without additional measures. In addition, the intrinsic compensation reduces the risk of making errors during the testing of the closed loop electrical connection. When there is no or only a minor mutual induction of the two coils then the coupling of the driving coil and the detection coil is only or mainly determined by the properties of the loop under test.

The above mentioned objective is obtained with this advantage because the compensation by means of a compensation loop makes the measurement less sensitive to the environmental conditions such as the distance to the loop under test. It further allows an easy detection of the resistance of the closed loop because only the phase difference between the current of the driving coil and the voltage of the detection coil have to be measured, not the amplitude of the signal as will be elucidated in detail below.

In another aspect it is an object to provide a method for testing a closed loop electrical connection, which method allows accurate contactless testing, is not complex and is easy to use. More in particular it is an objective to overcome problems and disadvantages of the above mentioned state of the art.

A method for testing a closed loop electrical connection is provided that comprises the steps of
providing an apparatus according to the invention,
adjusting the compensation loop to obtain a compensation of the direct mutual induction of the first and the second coil,
placing the apparatus and the closed loop electrical connection to be tested near each other,
obtaining a signal that is representative for the electrical resistance of the closed loop based on the voltage generated by the second coil.

An advantage of this method is that according to this method, once the compensation loop has been adjusted, no further calibration of the coil-loop combination is required. So, once a proper geometry of the loop has been found, the testing of closed loop electrical connections does not require special skills of the person performing the test.

### BRIEF DESCRIPTION OF THE FIGURES

FIG. 1A two interconnected photovoltaic cells

FIG. 1B a closed loop electrical connection

FIG. 2A an embodiment of the apparatus in a first planar measurement set-up

FIG. 2B an embodiment of the apparatus in a second planar measurement set-up

FIG. 3 an embodiment of the apparatus in a sandwich measurement set-up

FIG. 4 a preferred embodiment with planar geometry

FIG. 5 example of a compensation loop that is part of the detection coil

FIG. 6A top view of example of a compensation loop in the form of a closed separate winding

FIG. 6B side view of example of a compensation loop in the form of a closed separate winding

FIG. 7 example of two compensation loops connect with the coils

FIG. 8 embodiment of an electronic circuit

FIG. 9 embodiment of a hand held apparatus

FIG. 10 a flow chart of a method of compensation

### DETAILED DESCRIPTION OF EXEMPLARY EMBODIMENTS

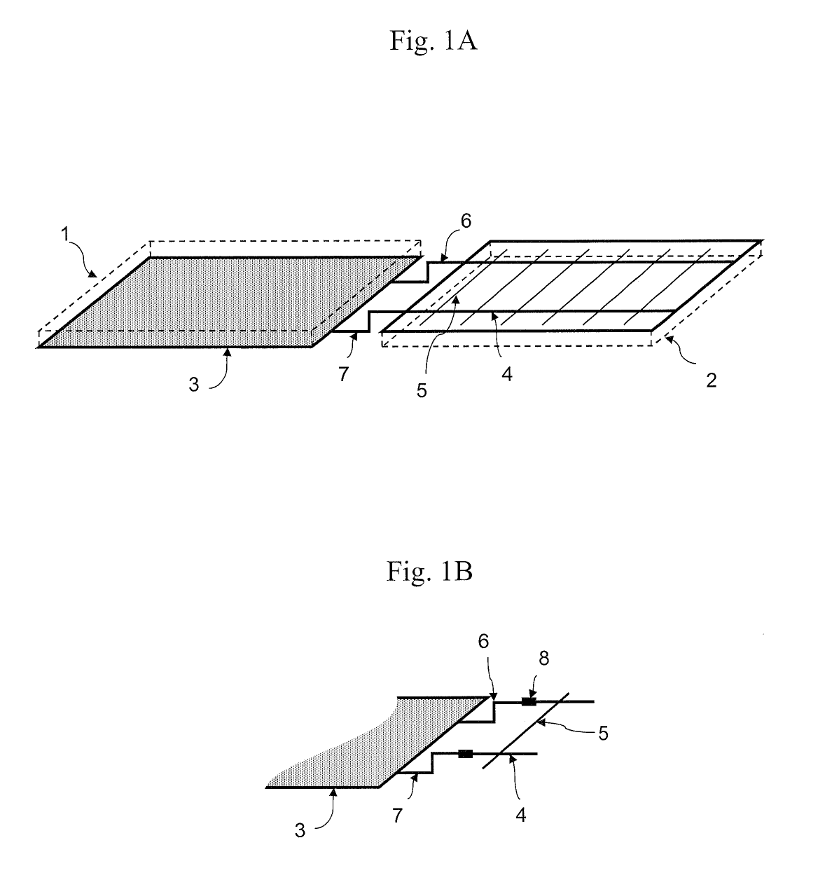

Photovoltaic cells or solar cells are semiconductor devices generating an electrical current when being subjected to light, more in particular to solar light. Often such solar cells are made out of silicon, either amorphous or (semi)crystalline silicon. Typically, the size of such a cell is approximately 15 by 15 centimeters (6 inch by 6 inch). Several photovoltaic cells are combined to solar panels which typically have a size of about one to two square meters. The voltage that is generated across a photovoltaic cell is typically only 0.5 Volt, whereas usually higher voltages are required. To obtain a higher voltage several photovoltaic cells of a panel are connected in series. In FIG. 1A is shown how two photovoltaic cells can be connected. For illustrative purpose only the back side of the left cell (1) and the front side of the right cell (2) are shown. The solar cells comprise a metallised layer (3) constituting the back side electrode and a structured conductive pattern at the front part of the cell, viz. the part of the cell that is directed towards the sun. Typically such a conductive pattern may comprise a few main tracks (4) with smaller branches (5). The main tracks are used for connecting the photovoltaic cell to a power consuming device or to another cell to form a solar panel.

Two photovoltaic cells may be connected in series by connecting the back side electrode of a first cell with the front side electrode of a second cell. Typically, the back electrode of a first cell may be connected via two wires (6), (7) with the front electrode of the second cell. In such a geometry the back electrode (3) of a first cell, the front electrode tracks (4), (5) of a second cell and the wirings (6), (7) form an electrically closed loop as shown in FIG. 1B. This loop may comprise solder connections (8).

In case that the cells are connected in parallel instead of in series, there will also be closed loop provided that the front electrodes and/or the two back electrodes of the two photovoltaic cells are connected by at least two conductive tracks forming a closed conductive loop.

The electrical conductivity of the loop is determined by, among others, the electrode structure and the quality of the interconnection of the cells, including possible solder connections. When only one type of photovoltaic cell is used and one type of connection between the cells is applied for making the solar panel, variations of the measured conductivity of different pairs of cells can be attributed to the quality of the interconnection between those cells because other properties such as the size of the loop, the electrode structure and the materials used are the same for all the loops under test.

Japanese patent publication JP2003-110122 discloses that the conductivity of the back electrode of a photovoltaic cell can be determined contactlessly by inducing a current in the electrode by means of an alternating magnetic field generated by a driving coil. The inventor has found that not only the conductivity of a homogeneous layer but also the conductivity of a closed loop can be determined in such a way. In such closed loop the induced current is confined geometrically to the conductive tracks forming the loop, whereas in case of a homogeneous layer the current is distributed over an area that is, among others, determined by the size of the driving coil.

An apparatus is provided that comprises two coils, a driving coil for generating a varying magnetic field and a detection coil for detecting a magnetic field. When a varying current flows through the driving coil, thereby circulating around an area of the coil, this coil generates a varying magnetic field around the coil, with a direction dependent on the direction of circulation of the current around the area, clockwise or counterclockwise. This varying magnetic field will induce an electrical current in a conductive loop that is placed in the vicinity of the coil. The loop may, for example, be formed by the interconnection of two photovoltaic cells as shown in FIG. 1B. The magnitude of the current depends, among others, on the relative orientation of the driving coil and the loop and on the electrical resistance of the loop. In case of an interconnection loop the resistance may, among others, be determined by solder connections (8) between wiring and electrodes. Preferably the area of the driving coil is less than the area of the loop under test, allowing the loop to enclose the maximum flux, also when the loop and coil are placed at a distance that is larger than, say, the diameter of the coil. However, the area of the coil may also be larger. In the latter case the calibration of the apparatus may need more attention and the output signal may be more sensitive for a varying distance between the coil and the loop, more in particular between the solar panel module under test and the apparatus comprising the driving coil.

The current in the loop under test will generate a magnetic field that will be picked-up by the detection coil. So the driving coil and the detection coil are coupled to each other via the loop under test. The strength of the coupling between the two coils largely depends on the properties of the loop, including for example the resistance of the connection between the solar cells. However, there is also a direct coupling, viz. a coupling that exists independently of the presence of a loop under test, between the two coils, which will influence the measurement. The inventor has found that this influence can be reduced or even eliminated by applying a compensation loop.

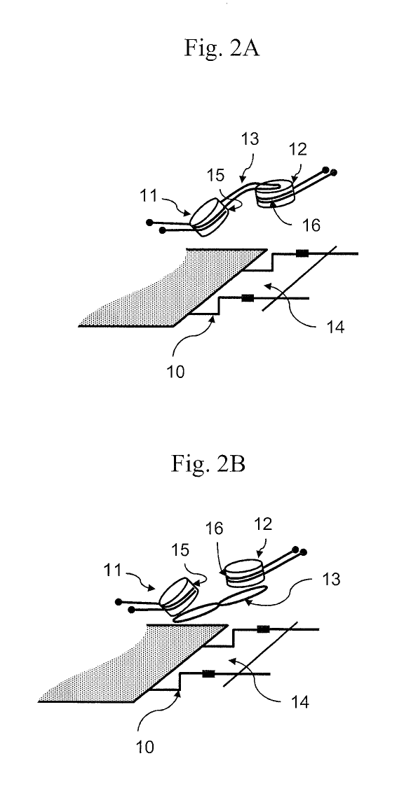

FIG. 2A shows a schematic drawing of an embodiment of the apparatus and a closed loop electrical connection that is under test. The measurement set-up shown is a planar set-up, viz. both the driving coil and the detection coil are at the same side of the loop under test. The driving coil (11) comprises a few windings (15) for generating a varying magnetic field in the area (14) enclosed by the closed loop electrical connection (10). In use, the driving coil will be connected to an electrical current source for generating a magnetic field and it will be placed relative to the loop under test in such a way that a varying magnetic flux will go through the closed loop via the area (14) enclosed by the loop. Although such a varying magnetic flux may be obtained by a driving coil that is moving, for example rotating, relative to the loop, a static coil is preferred because of a simpler construction and easier signal analysis. The embodiment further comprises a detection coil (12). This detection coil (12) also comprises a few windings (16). This detection coil may be structurally identical to the driving coil, but it may also differ in for example the number of winding and the size. When this detection coil is subject to a varying magnetic field generated by a current in the loop under test, there will be a voltage across the open ends of the coil. The ends of the coils are preferably connected to a voltage meter with a high input impedance. However, the ends of the coils may also be short circuited for measuring the current in the coil.

The dimensions of the driving coil and the detection coil may depend on the size of the loop under test. More in particular the dimensions of the coils and their position relative to each other will preferably be chosen so as that a projection of the coils on the area enclosed by the loop under test falls within that area. Among others such position and dimension allows testing of interconnection that are situated close to each other.

Those skilled in the art will appreciate that there is a mutual induction of the coils, more in particular that a voltage will be induced in the detection coil even in the absence of a closed loop. Or, in other words, that there is an electromagnetic coupling between the two coils. The strength of this coupling depends, among others, on the relative position and orientation of the two coils. To reduce this coupling, the apparatus further comprises a compensation loop (13) for compensating the direct mutual induction of the driving coil and the detection coil. In FIG. 2A, this compensation loop is shown as a part of the driving coil. However, as will be discussed in detail below, there are several other embodiments of the compensation loop.

During use of the apparatus the loop under test may face the coils as shown in FIG. 2A or the loop may face the compensation loop as shown in FIG. 2B. This implies that the compensation loop may be between the loop under test and the coils (see FIG. 2B) or that the coils may be situated between the loop under test and the compensation loop (see FIG. 2A).

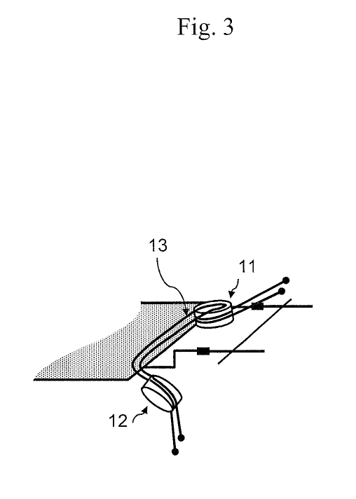

A geometry in which the apparatus during use is positioned at one side of the loop under test as shown in FIGS. 2A and 2B allows an easy test, in particular when the apparatus is used as a hand-held device. However, the loop under test may also be placed between the driving coil (11) and the detection coil (12) in a sandwich geometry as is shown in FIG. 3. Such a sandwich geometry makes it more difficult to compensate for the mutual induction of the driving coil and the detection coil than in the planar geometry because the compensation loop (13) is prone to pick up noise signals due to the relative large distance between the two coils. However, such a sandwich geometry might be useful under special circumstances, for example in an automated production process of solar modules where different sizes of interconnection loops have to be tested.

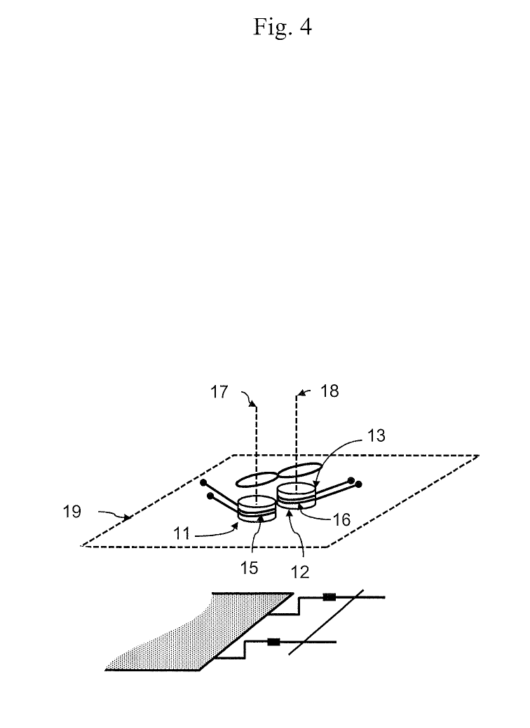

FIG. 4 shows a schematic drawing of a preferred embodiment with planar geometry. The apparatus comprises two coils in parallel, a driving coil (11) and a detection coil (12). In parallel is understood as that the axes (17,18) of the two coils have an angle as small as practically possible and the projections of the two coils on a plane perpendicular to the axes have at least substantially no overlap. So in the ideal situation this angle is 0 degrees but when put into practise the angle may for example be less than 5 degrees. Each of the coils comprises at least one winding (15,16). Preferably, the two coils are situated adjacent to each other in a plane (19) because in such a geometry the distance between the loop under test and the driving coil and between the loop under test and the detection coil is the same. In this case the areas of the coils are the areas in the plane around which the currents flow in the coils. However, one of the coils may also be displaced in the direction of an axis (17,18) perpendicular to the plane (19). In this case the areas of the coils are the areas in the planes of the coils around which the currents flow in the coils or, equivalently, their projections a common plane parallel to these planes.

During use, a varying current flows through the driving coil (11), generating a magnetic field in the direction of the axis (17). The varying current preferably is an alternating current (AC). The varying magnetic field induces a current in any closed conductive loop that is in the vicinity of the driving coil. For testing the interconnection of solar cells, this closed loop is formed by tracks, wires and solder connections as shown for example in FIG. 1B. The voltage across the detection coil (13) is a measure of the current in the loop under test, viz. of the electrical resistance of the loop.

Although the driving coil and the detection coil are placed in parallel to each other in the embodiment of FIG. 4, there will be a direct electromagnetic coupling between the two coils. Generally, a coil generates a dipole-like field that is some field strength adjacent the coil in a direction opposite to the field direction within the area of the coil, which results in coupling to an adjacent coil. Due to this coupling, the output voltage of the detection coil is not only determined by the properties of the loop under test but also by other factors. To eliminate, or at least reduce the direct coupling significantly, the apparatus further comprises a compensation loop (13) which will be discussed in detail below. During use the compensation loop may be situated between the coils and the loop under test as shown in FIG. 2B or the compensation loop and the loop under test may be at the opposite sides of the coils as shown in FIG. 2A.

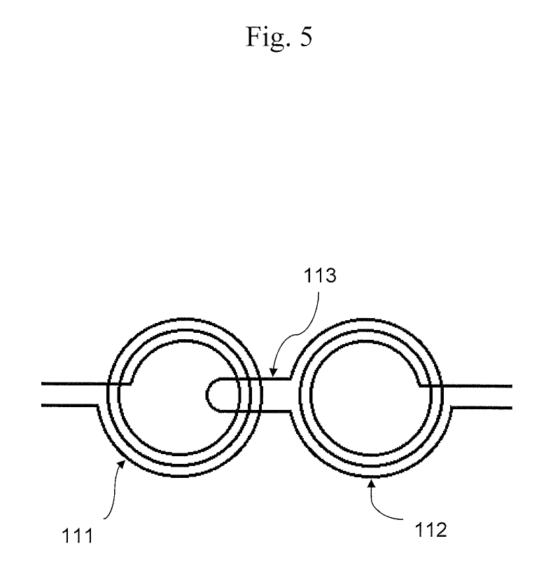

In one embodiment the compensation loop is part either of the detection coil or of the driving coil. The compensation loop comprises an extension of the coil, which extension at least partly covers the area of the other coil. That is, there is an overlap between projections of the compensation loop and the other coil on a plane perpendicular to the axis of the coils. So, if the extension (113) is part of the detection coil (112) as shown schematically in FIG. 5, than the extension will at least partly cover the driving coil (111). If the extension is part of the driving coil, the extension will at least partly cover the detection coil. It will be appreciated by those skilled in the art that there should be no galvanic contact between the extension and the coil of which the extension is not a part. In case that the detection coil and the driving coil are not made out of wires with an electrically insulating layer, special precautions have to be taken to avoid galvanic contact between the extension and the coil of which the extension is not a part.

The compensation loop overlapping the driving coil or the detection coil will compensate for the mutual induction of the driving coil and the detection coil. As current flows through the overlapping extension in the same direction of circulation around the area of the extension (clockwise or counterclockwise in the plane) as around the area of the coil from which it extends, the magnetic field in the extension has a compensating effect on the field in the coil from which is extends. The exact dimensions and geometry of the extension and the amount of overlap can be determined for example experimentally by minimizing the signal in the detection coil in absence of the loop under test and any other closed conductive path.

An advantageous property of this embodiment is its simple construction and therefore easy manufacturing. More in particular, one coil (111) can for example be attached to one side of a substrate, like for example a printed circuit board or foil, and the other coil (112), including the extension (113) to the opposite site. The two coils can also be attached to the same side of the substrate, whereas the extension is conducted through the substrate from the coil to the other side of the substrate to cover at least partially the other coil. In this embodiment the substrate supports the coils and provides electrical isolation between the extension of the one coil and the other coil.

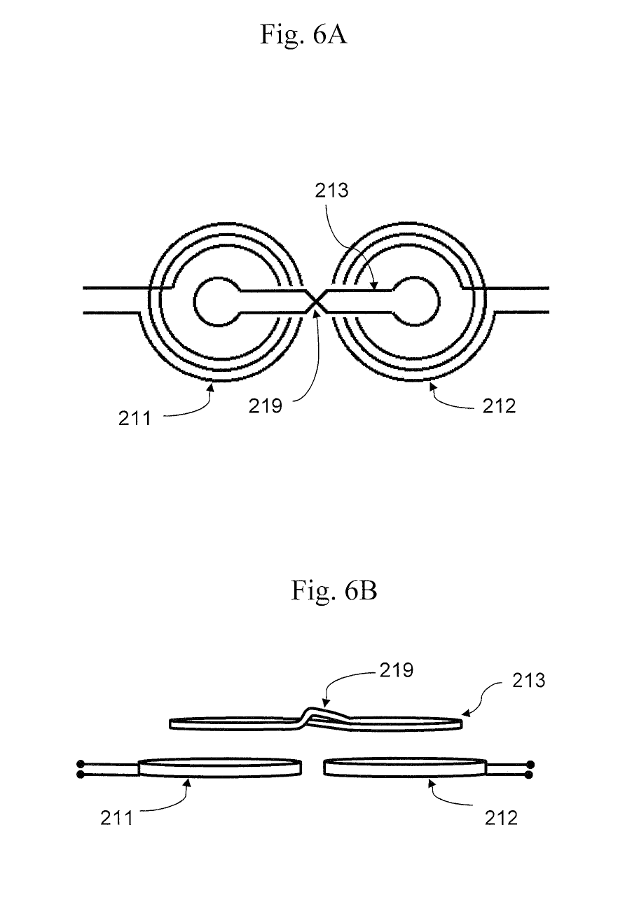

In another embodiment of the apparatus the loop is a closed separate winding as shown schematically in FIG. 6A. In this embodiment the winding is a turned winding (shaped for example like a number 8) with a first and second winding part, circulating around a first and second part of the area of the loop, with the first and second winding parts configured so that current flows in mutually opposite directions of circulation around the first and second parts of the area respectively (clockwise and counterclockwise in the plane). Thus, the turned winding is configured so that there will be no net current when the winding is subject to a magnetic flux because the induced current in one part of the loop will counteract the current in the other—turned—part of the loop. The compensation loop is situated in the vicinity of the driving coil and the detecting coil such that the perpendicular projection of the turned winding on the plane of driving and detection coil mainly coincides with the two coils. This allows the turned compensation loop to enclose the maximum magnetic flux. Preferably, the perpendicular projection of the first and second part of the area only overlap or mainly coincide with the driving coil and the detecting coil respectively. FIG. 6A shows a top or bottom view in the direction of the axes of the coils. FIG. 6B a front or side view. In case when the driving coil and the detection coil are identical, also the two parts of the turned winding should be identical, viz. the area of the two turned parts of the loop should be the same. The loop can, for example, be made for out of wire or can be a conductive pattern on for example a printed circuit board or foil. For proper functioning, the wire may be covered with an electrically isolating material. This isolation may cover the whole wire or only cover it partially at the position (219) where the two parts of the loop cross each other as to avoid electrical contact at the crossing position.

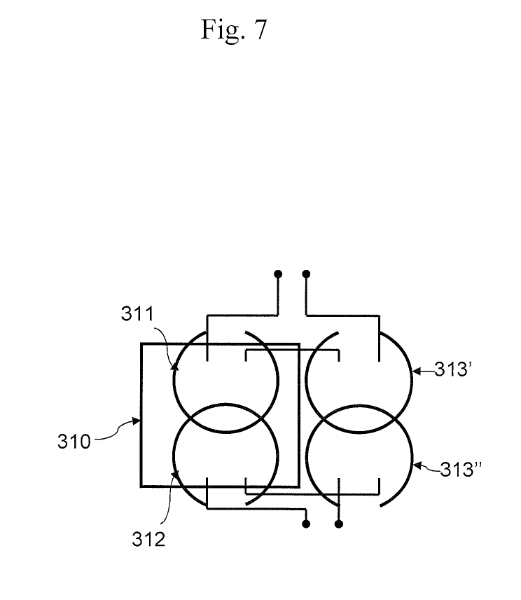

In another apparatus that solves the problem of mutual induction a first compensation loop is a winding in series with the driving coil and a second compensation loop is a winding or a coil comprising a multiple of windings in series with the detection coil. FIG. 7 shows such an embodiment. The first (313′) and second (313″) compensation loops are situated relative to each other in the same way as are the driving coil (311) and the detection coil (312). However, the compensation loops are situated such that when the apparatus is in use, the two compensation loops are not coupled via a conductive path, more in particular that they are not coupled via the interconnection loop (310) that has to be tested. The direction of the winding or windings of the compensation loop in series with the driving coil is opposite to the direction of the winding or windings of the compensation loop in series with the detection coil such that in absence of the loop under test or any other closed conductive path, the induced voltages over the detection coil and the compensation coil in series with the detection coil have equal magnitudes but opposite signs, leading to a zero induced voltage over the two coils in series.

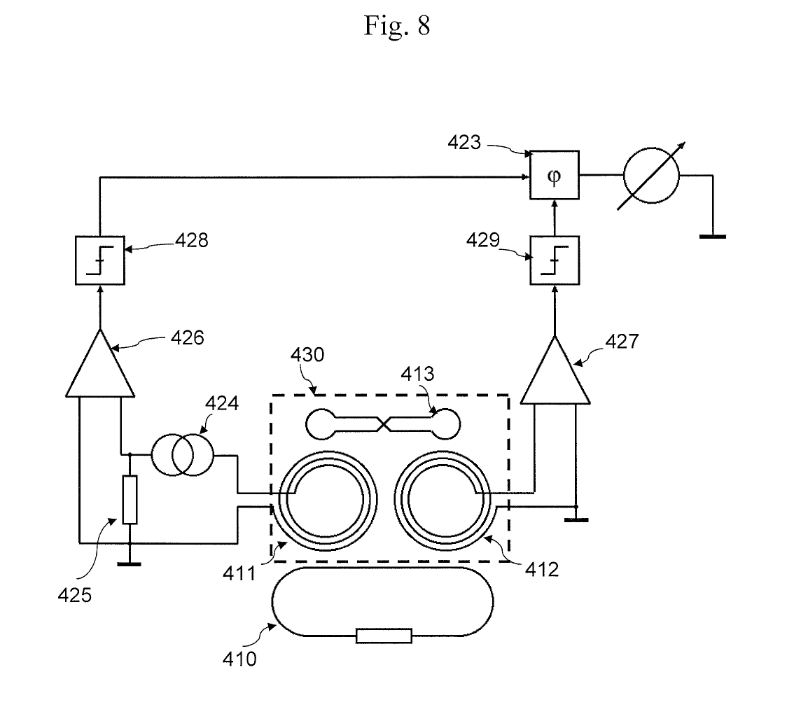

In an embodiment the apparatus may comprise specific electronics that allow determining the difference in phase between the current in the driving coil and the voltage across the detection coil. Such an embodiment is shown in FIG. 8. In this embodiment a turned loop (413) is used as compensation loop. However, the specific electronics can also be applied in combination with different compensation loops. More in particular, the coil-loop combination (430) preferably is the combination as shown in FIG. 5, whereby the extension is either part of the driving coil or part of the detection coil. A current source (424) supplies the driving coil (411) with an alternating current with a frequency f. The current is transferred to a voltage via a resistor (425). The voltage is amplified by an amplifier (426) and clipped (428) to the maximum amplitude the amplifier can generate. This results in a block wave comprising the information about the phase of the current in coil (411). The voltage that is induced in the detection coil (412) is amplified by mains of a high impedance input amplifier (427) and clipped (429) to the maximum amplitude the amplifier can generate, resulting in a block wave comprising the information about the phase of the voltage across the detection coil. The signal with the phase information of the driving coil and the signal with the phase information from the detection coil are fed to a phase comparator (423) which gives an output signal that is representative for the phase difference. This phase difference is a measure for the electrical resistance of the loop under test as is explained below.

The relationship between the currents and the voltages in the driving coil with inductance L₁, detection coil with inductance L₂ and the interconnection loop with inductance L₃ is given by the following expressions in which index 1 relates to the driving coil, index 2 to the detection coil and index 3 to the interconnection loop:

U₁=jωL₁I₁+jωM₁₂I₂+jωM₁₃I₃

U₂=jωM₂₁I₁+jωL₂I₂+jωM₂₃I₃

U₃=jωM₃₁I₁+jωM₃₂I₂+jωL₃I₃

Here, ω is the angular frequency and M is the mutual induction of coils and loop. Because the mutual induction of the driving coil and the detection coil is neutralized by the compensation loop, the inductions M₁₂ (driving coil—detection coil) and M₂₁ (detection coil—driving coil) can be omitted. Further, the high impedance of the input of the amplifier suppresses the current I₂ in the detection coil:

U₁=jωL₁I₁+jωM₁₃I₃

U₂=jωM₂₃I₃

U₃=jωM₃₁I₁+jωL₃I₃

Further, the current in the interconnection loop is determined by the resistance R of that loop:

U₃=−I₃R

The relationship between the voltage U₂ across the detection coil and the current I₁ in the driving coil therefore is given by:

$${U}_{2} = \frac{{ω}^{2} {M}_{31} {M}_{23}}{( R + j ω {L}_{3} )} {I}_{1}$$

This time-dependent voltage has amplitude and a phase. The phase of the voltage is given by:

$$φ = arctan ( \frac{- ω {L}_{3}}{R} )$$

This phase is determined by the induction L₃ of the interconnection loop, viz. the dimension of the loop, the frequency of the applied current and the resistance of the interconnection loop. This equation illustrates that only measuring the difference in the phase of the current in the driving coil and the voltage across the detection coil satisfies for determining the resistance R of the interconnection if the inductance of the interconnection is known:

$$R = - \frac{ω {L}_{3}}{tan ( φ )}$$

The frequency can be chosen to have an optimal reading of an expected resistance range and a given inductance. For testing of interconnections in solar panels it is not always essential that the value of the resistance is known. It might satisfy that there is an indication, in the form of a different phase difference, that the interconnection under test has a higher resistance than a pre-set value. So, for example in an automated quality control, a critical phase difference can be set for acceptance of the interconnection.

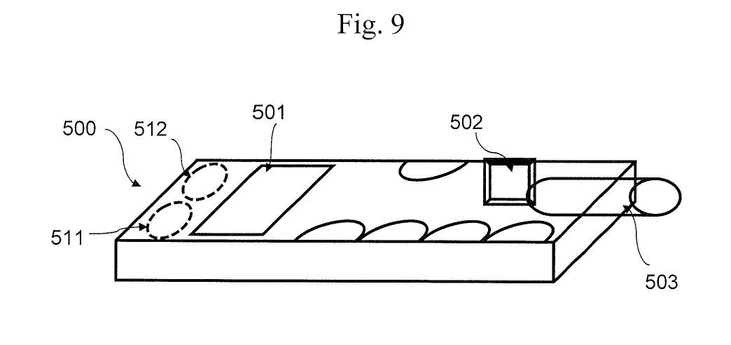

In a further embodiment, the apparatus can be hand-held for testing the connections. A schematic example of such a light weight portable embodiment is shown in FIG. 9. It is advantageous that such a hand held apparatus comprises a space for holding a battery (503) with electrodes for connection to the battery (503), in order to test connections of, for instance, solar panels at places that are not easily accessible, like for example on roofs of houses. Battery (503) may either rechargeable or non-rechargeable. The apparatus can be switched on and off by an on/off button (502) to save the battery when the apparatus is not in use. The apparatus further may comprise a display (501) either just to indicate whether a connection under test satisfies pre-set characteristics or to show a characteristic parameter of the loop under test, for example the resistance of the loop or the phase difference between the current in the driving coil (511) and the voltage across the detection coil (512). Instead of the display or in addition to the display the apparatus may comprise an optical indicator, for example a Light Emitting Diode or an acoustic indicator for indicating whether the loop under test satisfies pre-set conditions. The apparatus may comprise an electronic circuit as shown in FIG. 8 or any other suitable circuit and it may comprise an electronic memory for storing information and measurement data.

In a still further embodiment the apparatus is part of an automated production line for the production of solar panels. In such an embodiment the apparatus may comprise electronics for automated control of the connections. For example an alarm signal may be given as optic or acoustic signal indicating that the apparatus detected a bad connection. For quality safeguarding the apparatus may comprise a memory for a database comprising the measured properties of the interconnections for future consultation.

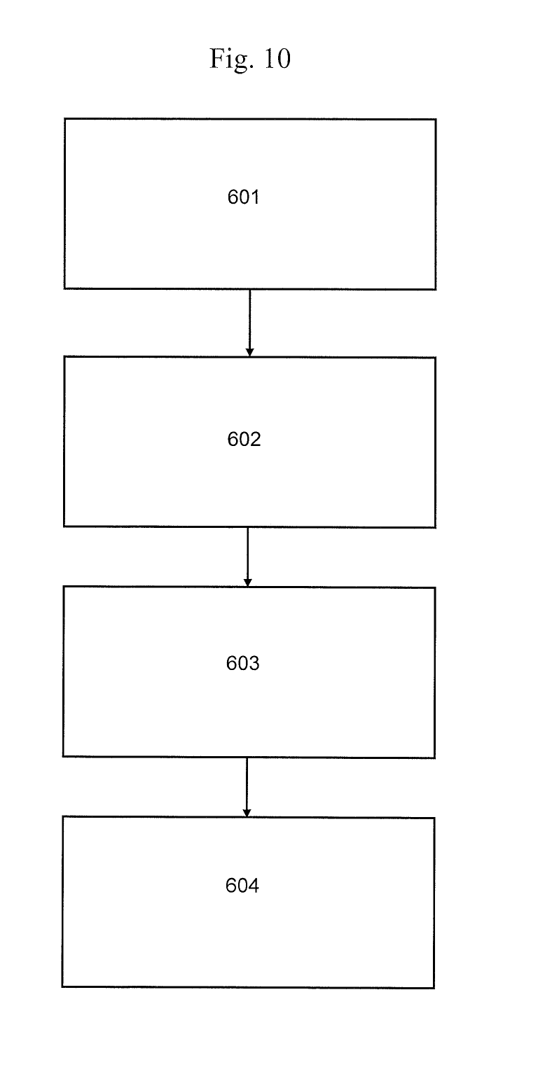

FIG. 10 shows a flow chart of a method for testing a closed loop electrical connection. This method may advantageously use the apparatus described with reference to the preceding figures. As described above, the optimal geometry of the coil-loop combination may be determined experimentally in an adjustment step 602. This adjustment (602) for finding the optimal geometry can either be performed by model calculations or physically by varying the geometry of a coil-loop combination. This adjustment step preferably is part of the design step of the apparatus. For determining the optimal geometry, use can be made of the electronics as described above and shown in FIG. 8. However, those skilled in the art are familiar with other methods of measuring the mutual induction of the coils.

Once the geometry of the coil-loop combination has been fixed, the apparatus is ready for use. During use a first step 603 is performed wherein the apparatus and the closed loop electrical connection to be tested are placed near each other in such a way that the apparatus functions properly, viz. that the driving coil can induce a current in the loop to be tested and that the detection coil can pick up the magnetic field generated by the loop. A current is supplied through the driving coil. As a result, the compensation loop is used to pick up part of the generated field, or generate a compensating field and compensate for mutual induction. In a second step 604 the apparatus is used for obtaining a signal that is representative for the electrical resistance of the closed loop based on the voltage generated by the second coil. In an embodiment this signal may be the phase as described above, or any other signal, including optical signals.

### EXAMPLE

Frequency of the current in the driving coil is 1 MHz. The driving coil and the detection coil comprising a compensation loop in the form of an extension having an inductance of 691 nH and 706 nH respectively. A typical distance between the loop under test and the driving coil is 5 mm. This was shown to give good results for an interconnection with a typical dimension of 3 mm.

1. Apparatus for testing a closed loop electrical connection, the apparatus comprising
a first coil comprising at least one first winding enclosing a first coil area for generating a varying magnetic field in a loop area enclosed by the closed loop electrical connection, and
a second coil comprising at least one second winding enclosing a second coil area for generating a voltage when being subjected to the magnetic field generated by the current in the closed loop electrical connection,
a compensation loop for compensating direct mutual induction of the first coil and the second coil, which compensation loop at least partially covers one of the first and second coil areas or both the first and second coil areas.

2. Apparatus according to claim 1, wherein the compensation loop is configured to intrinsically compensate any direct mutual induction of the first coil and the second coil.

3. Apparatus according to claim 1, wherein the compensation loop comprises a part of the second coil overlapping the first coil.

4. Apparatus according to claim 1, wherein the first coil and the second coil are located adjacent to each other in a same plane or parallel planes with an offset between the parallel planes, and wherein the compensation loop comprises a part of the first or second coil, extending from a main part of the first or second coil in the plane of the first or second coil, overlapping the second or first coil when the compensation loop comprises a part of the first or second coil respectively.

5. Apparatus according to claim 1, wherein the compensation loop comprises a turned loop overlapping the first coil and the second coil.

6. Apparatus according to claim 1, wherein the first coil and the second coil are located adjacent to each other in a same plane or parallel planes with an offset between the parallel planes, and wherein the compensation loop comprises a turned loop in a further plane parallel to said plane, the turned loop having first and second parts running at least partly around a first and second part of the area of the turned loop, wherein directions of circulation of current through first and second parts around the first and second part of the area are mutually opposite, the first and second part of the area overlapping the first coil and the second coil respectively.

7. Apparatus according to claim 1, further comprising an electronic circuit for determining the difference in phase between the current in the first coil and the voltage across the second coil.

8. Apparatus according to claim 1, configured for operation by battery power.

9. Apparatus according to claim 1, wherein the apparatus is hand-held.

10. Apparatus according to claim 1, wherein a first axis perpendicular to the at least one first winding and a second axis perpendicular to the at least one second winding are parallel.

11. Apparatus according to claim 1, wherein the first winding and the second winding are situated in a same plane.

12. Method for testing a closed loop electrical connection comprising the steps of
generating a varying magnetic field in a loop area enclosed by the closed loop electrical connection, using a first coil comprising at least one first winding enclosing a first coil area;
subjecting a second coil to a magnetic field generated by induced current in the closed loop electrical connection, thereby generating a voltage from the second coil, the second coil comprising at least one second winding enclosing a second coil area,
using a compensation loop that at least partially covers one of the first and second coil areas or both the first and second coil areas to compensate direct mutual induction of the first coil and the second coil, and
obtaining a signal that is representative for the electrical resistance of the closed loop electrical connection based on the voltage generated by the second coil.

13. Method according to claim 12 wherein the closed loop electrical connection is an electrical interconnection of photovoltaic cells in a solar module comprising a multiple of photovoltaic cells.
